(19) United States
(12) Patent Application Publication
(10) Pub. No.: US 2026/0353707 A1
(43) Pub. Date: Nov. 5, 2026

(54) SEMICONDUCTOR DEVICE

(71) Applicant: Minebea Power Semiconductor Device Inc., Hitachi-shi, Ibaraki (JP)

(72) Inventors: Tomoka SUEMATSU, Tokyo (JP); Takeru SUTO, Tokyo (JP); Haruka SHIMIZU, Tokyo (JP); Yuki TSUJIKAWA, Tokyo (JP)

(21) Appl. No.: 19/488,908

(22) PCT Filed: Feb. 15, 2024
(86) PCT No.: PCT/JP2024/005275

§ 371 Date: Dec. 1, 2025

(30) Foreign Application Priority Data
Jun. 14, 2023 (JP) 2023-097377

(51) Int. Cl. H10D 30/66; H10D 62/10; H10D 62/17

(52) U.S. Cl. CPC H10D 30/668; H10D 62/103; H10D 62/393

(57) ABSTRACT

A semiconductor device includes a high degree of freedom in the design of a width of a channel region and a width of a JFET region in a trench MOSFET having a vertical channel fin structure. The trench MOSFET having the vertical channel fin structure includes end parts in a width direction of bottom surfaces of a plurality of trenches that are disposed in body regions. The channel region is connected to the body regions, and a channel current flows in the channel region in the vertical direction. The JFET region includes a first JFET region and a second JFET region disposed closer to a side of the channel region than the first JFET region. The width of the second JFET region is larger than the width of the first JFET region.

### TECHNICAL FIELD

The present invention relates to a semiconductor device.

### BACKGROUND ART

A trench MOSFET having a vertical channel fin structure has been proposed as one type of a trench type MOSFET.

FIG. 17 is a perspective view schematically describing a structure of a trench MOSFET having a conventional vertical channel fin structure. Note that, in FIG. 17, illustrations of gate electrodes, a gate insulating film, an interlayer insulating film, source electrodes, and a drain electrode are omitted.

A conventional semiconductor device 1 illustrated in FIG. 17 includes a plurality of trenches 2 that have a longitudinal direction in a first direction and a lateral direction in a second direction in plan view, and are aligned in the second direction. Note that the trench 2 indicated by a dotted line in the cross section in the front in FIG. 17 virtually indicates positions corresponding to the trenches 2 in order to describe the positional relationship between other components and the trenches 2.

A source region 3 of a first conductivity type includes a region that has a fin structure at least partially partitioned by the plurality of trenches 2. A channel region 5 of a second conductivity type having a fin structure partitioned by the plurality of trenches 2 is formed on a lower surface of the source region 3 and in contact with the source region 3. A JFET region 8 of the first conductivity type is formed below the channel region 5, and body regions 9 of the second conductivity type are formed on lateral sides of the JFET region 8. End parts in the first direction of the bottom surfaces of the plurality of trenches 2 are disposed in the body regions 9. The channel region 5 is connected to the body regions 9. A drift region 10 of the first conductivity type is formed below the JFET region 8, and a drain region 11 of the first conductivity type is formed below the drift region 10.

Furthermore, the conventional semiconductor device 1 illustrated in FIG. 17 includes a gate insulating film disposed inside the trenches 2 and a gate electrode including a region at least partially disposed in the trenches 2, and a channel current flows in the vertical direction (depth direction) in the channel region 5. Note that the gate electrode buried inside the trenches 2 are connected to each other outside the trenches 2.

Note that Patent Literature related to such a technique includes, for example, Patent Literature 1, and, although names and detailed structures of components are different, paragraphs 0048 to 0052, and FIG. 3 and 14 to 18 of Patent Literature 1 describe a configuration similar to that in FIG. 17 described above.

### CITATION LIST

### Patent Literature

Patent Literature 1: Japanese Patent Application Publication No. 2004-207289

### SUMMARY OF INVENTION

### Technical Problem

This structure of the conventional semiconductor device 1 illustrated in FIG. 17 can increase the number of channels by shortening a trench pitch and increasing a channel density, and reduce an on-resistance as viewed from an entire semiconductor chip.

Furthermore, there is the JFET region 8 formed between the body regions 9, a depletion layer extends from the body regions 9 to the JFET region 8 at a time of short-circuiting and pinches off, and therefore a short circuit withstand time is great.

Furthermore, end parts in the first direction of the bottom surfaces of the plurality of trenches 2 are disposed in the body regions 9 in this structure, and therefore three-dimensional corners of the trenches 2 are present in the body regions 9 in this structure. Consequently, at the three-dimensional corner portions of the trenches 2 in which the electric field is likely to concentrate and breakdown of the gate insulating film is likely to occur, concentration of an electric field is relaxed even at a time of application of a high voltage, so that it is possible suppress breakdown of the gate insulating film.

Here, it is also possible to reduce the on-resistance by increasing the width of the channel region 5 (the length in the first direction of the channel region 5) and reducing a channel resistance.

However, in the structure of the conventional semiconductor device 1 illustrated in FIG. 17, the channel region 5 has a fin Structure partitioned by the plurality of trenches 2, the end parts in the first direction of the bottom surfaces of the plurality of trenches 2 are disposed in the body regions 9, and the channel region 5 is connected to the body regions 9 in this structure, and the width of the channel region 5 is a width obtained by subtracting overlapping widths of the trenches 2 and the body regions 9 from the width in a longitudinal direction of the trenches 2 (the length in the first direction of the trenches 2), and the width of the channel region 5 and the width of the JFET region 8 (the length in the first direction of the JFET region 8) just below the channel region 5 are the same. Accordingly, there is a problem that the width of the channel region 5 and the width of the JFET region 8 just below the channel region 5 cannot be designed independently, and, when the width of the channel region 5 is increased and the on-resistance is reduced to improve performance, the width of the JFET region 8 becomes large, a short circuit withstand time and a breakdown voltage lower, and reliability lowers, and performance and reliability have a trade-off relationship.

A problem to be solved by the present invention is to implement a semiconductor device in which the degree of freedom of a design of the width of a channel region and the width of a JFET region is high in a trench MOSFET having a vertical channel fin structure.

### Solution to Problem

To solve the above problem, a semiconductor device according to the present invention includes: a plurality of trenches that have a longitudinal direction in a first direction and have a lateral direction in a second direction in plan view, and are aligned in the second direction; a source region of a first conductivity type that includes a region having a fin structure at least partially partitioned by the plurality of trenches; a channel region of a second conductivity type that is in contact with a lower surface of the source region and has a fin structure partitioned by the plurality of trenches; a gate insulating film that is disposed inside the trenches; a gate electrode that includes a region at least partially disposed inside the trenches; a JFET region of the first conductivity type that is disposed below the channel region; and a body region of the second conductivity type that is disposed on a lateral side of the JFET region, end parts in the first direction of bottom surfaces of the plurality of trenches are disposed in the body region, the channel region is connected to the body region, and a channel current flows in the channel region in a vertical direction, the JFET region includes a first JFET region and a second JFET region disposed closer to a side of the channel region than the first JFET region, and a length in the first direction of the second JFET region is longer than a length in the first direction of the first JFET region.

### Advantageous Effects of Invention

According to the present invention, it is possible to implement a semiconductor device in which the degree of freedom of a design of the width of a channel region and the width of a JFET region is high in a trench MOSFET having a vertical channel fin structure.

### BRIEF DESCRIPTION OF DRAWINGS

FIG. 1 is a perspective view illustrating a schematic configuration of a semiconductor device according to Embodiment 1.

FIG. 2 is a cross-sectional view taken along line X1-X1′ in FIG. 1.

FIG. 3 is a cross-sectional view taken along line X2-X2′ in FIG. 1.

FIG. 4 is a cross-sectional view taken along line Y1-Y1′ in FIG. 1.

FIG. 5 is a cross-sectional view taken along line X1-X1′, corresponding to FIG. 2, and illustrating another example of the schematic configuration of the semiconductor device according to Embodiment 1.

FIG. 6 is a cross-sectional view taken along line X1-X1′ and illustrating the schematic configuration of the semiconductor device according to Embodiment 2, and is a diagram schematically illustrating expansion of a depletion layer at a time of a normal operation.

FIG. 7 is a cross-sectional view taken along line X1-X1′ and illustrating the schematic configuration of the semiconductor device according to Embodiment 2, and is a diagram schematically illustrating expansion of the depletion layer at a time of short-circuiting or at a time of blocking.

FIG. 8 is a diagram illustrating trade-off between performance and reliability in a case of a design focusing on reliability of the semiconductor device according to Embodiment 2.

FIG. 9 is a diagram illustrating trade-off between performance and reliability in a case of a design focusing on performance of the semiconductor device according to Embodiment 2.

FIG. 10 is a cross-sectional view taken along line X1-X1′ and illustrating the schematic configuration of the semiconductor device according to Embodiment 3, and is a diagram schematically illustrating expansion of the depletion layer at a time of short-circuiting or at a time of blocking.

FIG. 11 is a cross-sectional view taken along line X1-X1′ and illustrating the schematic configuration of the semiconductor device according to Embodiment 4.

FIG. 12 is a diagram illustrating an impurity concentration profile in a depth direction along line Z1-Z1′ in FIG. 11.

FIG. 13 is a cross-sectional view taken along line X1-X1′ and illustrating the schematic configuration of the semiconductor device according to Embodiment 5.

FIG. 14 is a diagram describing a relationship between an integration value of a dose amount of a JFET region and the electric field of a gate insulating film in the semiconductor device according to Embodiment 6.

FIG. 15 is a cross-sectional view taken along line X1-X1′ and describing a manufacturing method of the semiconductor device according to Embodiment 7.

FIG. 16 is a diagram describing the manufacturing method of the semiconductor device according to Embodiment 7, and illustrating an impurity concentration profile in the depth direction along line Z2-Z2′ FIG. 15.

FIG. 17 is a perspective view schematically describing a structure of a trench MOSFET having a conventional vertical channel fin structure.

### DESCRIPTION OF EMBODIMENTS

Hereinafter, embodiments of the present invention will be described with reference to the drawings. In each drawing and in each embodiment, identical reference symbols will be assigned to identical or similar constituent components, and duplicate description thereof will be omitted.

### Embodiment 1

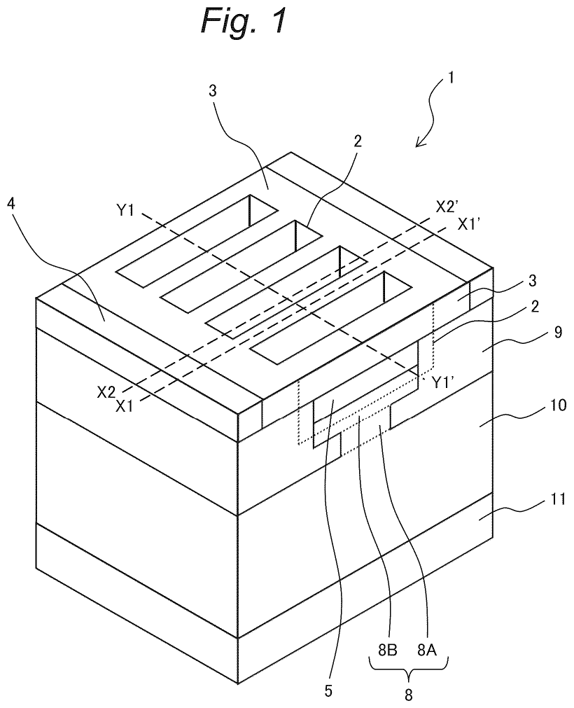

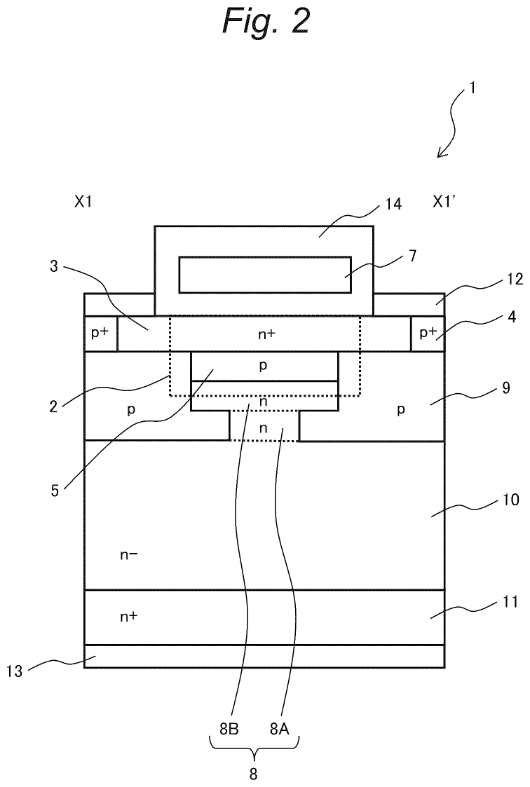

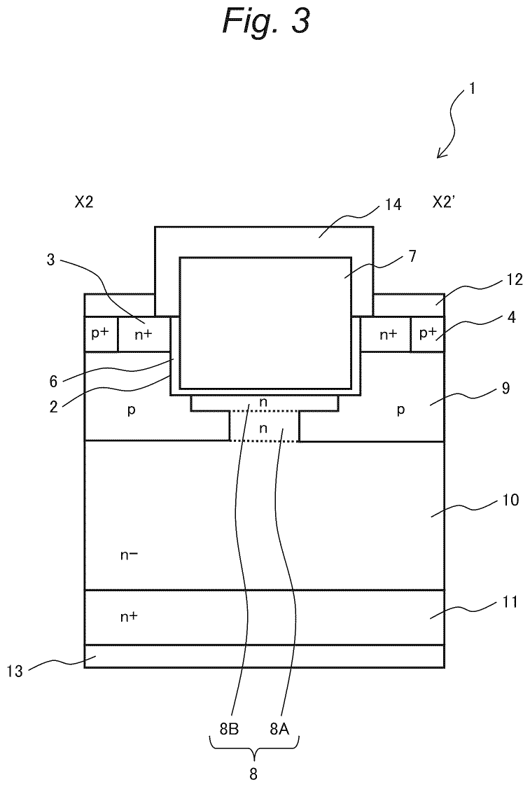

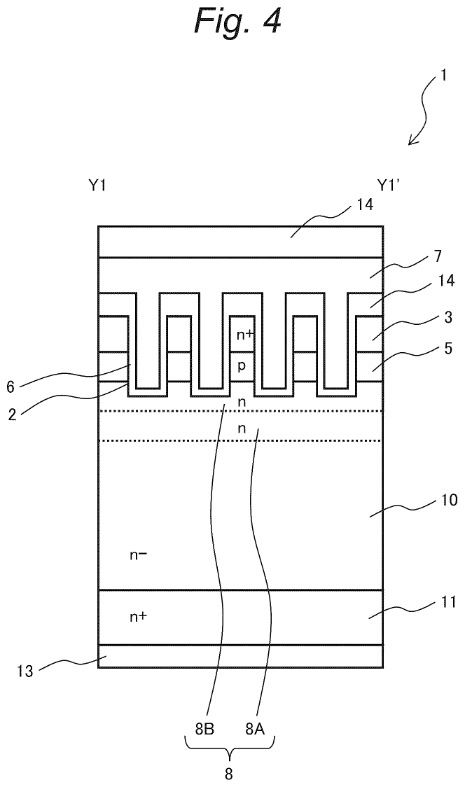

FIG. 1 is a perspective view illustrating a schematic configuration of a semiconductor device according to Embodiment 1. FIG. 2 is a cross-sectional view taken along line X1-X1′ in FIG. 1. FIG. 3 is a cross-sectional view taken along line X2-X2′ in FIG. 1. FIG. 4 is a cross-sectional view taken along line Y1-Y1′ in FIG. 1. Note that, in FIG. 1, illustrations of a gate electrode 7, a gate insulating film 6, an interlayer insulating film 14, a source electrode 12, and a drain electrode 13 are omitted.

A semiconductor device 1 according to the present embodiment includes a plurality of trenches 2, a source region 3 of a first conductivity type, a channel region 5 of a second conductivity type, the gate insulating film 6, the gate electrode 7, a JFET region 8 of the first conductivity type, and body regions 9 of the second conductivity type.

The present embodiment will describe an example where the first conductivity type is an n-type and the second conductivity type is a p-type, yet is not limited thereto, and the first conductivity type may be the p-type and the second conductivity type may be the n-type.

The plurality of trenches 2 have a longitudinal direction in a first direction (a direction along line X1-X1′ in FIG. 1) and a lateral direction in a second direction (a direction along line Y1-Y1′ in FIG. 1) in plan view, and are aligned in the second direction. Note that the trench 2 indicated by a dotted line in the cross sections in FIGS. 1 and 2 virtually indicates a position corresponding to the trenches 2 to describe the positional relationship between other components and the trenches 2.

The source region 3 of the first conductivity type includes a region having a fin structure at least partially partitioned by the plurality of trenches 2. The channel region 5 of the second conductivity type having the fin structure partitioned by the plurality of trenches 2 is formed on a lower surface of the source region 3 and in contact with the source region 3. The JFET region 8 of the first conductivity type is formed below the channel region 5, and the body regions 9 of the second conductivity type are formed on lateral sides of the JFET region 8. The channel region 5 is connected to the body regions 9. Accordingly, the width of the channel region 5 is a width obtained by subtracting an overlapping width of the trenches 2 and the body regions 9 from the width in the longitudinal direction of the trench 2.

The gate insulating film 6 is disposed inside the trenches 2. Furthermore, at least part of a region of the gate electrode 7 is disposed inside the trenches 2. Note that the gate electrode 7 disposed inside the trenches 2 is connected to each other outside the trenches 2. The gate electrode 7 can be formed of, for example, polysilicon.

In the semiconductor device 1 according to the present embodiment, a gate drive signal is input to the gate electrode 7 inside the trench 2 to perform control, so that a channel current flows in the channel region 5 of the fin structure in a vertical direction (depth direction). That is, the trench MOSFET has a vertical channel fin structure. Consequently, it is possible to increase the number of channels by shortening a trench pitch and increasing a channel density, so that it is possible to reduce an on-resistance as viewed from an entire semiconductor chip. Furthermore, there are the JFET region 8 formed between the body regions 9, a depletion layer extends from the body regions 9 to the JFET region 8 at a time of short-circuiting and pinches off, and therefore a short circuit withstand time is great.

Note that the semiconductor device 1 according to the present embodiment additionally includes a drift region 10 of the first conductivity type disposed below the JFET region 8, a drain region 11 of the first conductivity type disposed below the drift region 10, the source electrode 12 disposed on the front surface side, the drain electrode 13 disposed on a back surface side, and the interlayer insulating film 14.

The source electrode 12 is an electrode formed of, for example, a metal such as aluminum and is electrically connected to the source region 3. The present embodiment will be described using an example where the source electrode 12 is electrically connected with the body regions 9 with the contact region 4 of the second conductivity type interposed therebetween and having an impurity concentration higher than those of the body regions 9, yet is not limited thereto, and the source electrode 12 may be connected directly with the body regions 9.

The drain electrode 13 is an electrode formed of, for example, a metal such as aluminum, and is electrically connected with the drain region 11.

The interlayer insulating film 14 is formed between the portions of the gate electrode 7 connected to each other and the source region 3. Furthermore, the interlayer insulating film 14 is also formed so as to cover upper parts and side parts of the portions of the gate electrodes 7 connected to each other.

In the semiconductor device 1 according to the present embodiment, the end parts in the first direction of the bottom surfaces of the plurality of trenches 2 are disposed in the body regions 9. Consequently, three-dimensional corners of the trenches 2 are present in the body regions 9 in this structure. Accordingly, at the three-dimensional corner portions of the trenches 2 in which the electric field is likely to concentrate and breakage of the gate insulating film 6 is likely to occur, concentration of an electric field is relaxed even at a time of application of a high voltage, so that it is possible to suppress breakage of the gate insulating film 6.

Furthermore, in the semiconductor device 1 according to the present embodiment, the JFET region 8 includes a first JFET region 8A and a second JFET region 8B disposed closer to a side of the channel region 5 than the first JFET region 8A, and the width of the second JFET region 8B (the length in the first direction of the second JFET region 8B) is formed longer than the width of the first JFET region 8A (the length in the first direction of the first JFET region 8A). Consequently, even in a state where there is such a restriction that the width of the channel region 5 and the width of the second JFET region 8B just below the channel region 5 are equal, the width of the channel region 5 and the width of the first JFET region 8A are not affected by this restriction, and both can be independently designed. Furthermore, as the width of the JFET region 8 is smaller, the depletion layer extending from the body regions 9 to the JFET region 8 at the time of short-circuiting is more likely to be closed and pinch off in the JFET region 8, so that a short circuit withstand time becomes great. Accordingly, by increasing the width of the channel region 5 and reducing the on-resistance, and, on the other hand, making the width of the first JFET region 8A smaller than that of the channel region 5 to improve the performance, a sufficient short circuit withstand time and a breakdown voltage can be secured, so that it is also possible to secure reliability, and, compared to a case where there is only one type of the width of the JFET region 8 as in a conventional technique, it is possible to increase the degree of freedom of design, improve a trade-off relationship between performance and reliability, and make both the performance and the reliability compatible. Furthermore, the width of the first JFET region 8A can be changed independently of the width of the channel region 5 according to a required breakdown voltage, so that it is easy to change the design.

As described above, according to the present embodiment, in the trench MOSFET having the vertical channel fin structure, it is possible to implement the semiconductor device 1 in which the degree of freedom of a design of the width of the channel region 5 and the width of the JFET region 8 is high.

Note that the position in the depth direction of a lower end of the gate electrode 7 disposed inside the trenches 2 desirably overlaps the position in the depth direction of the second JFET region 8B. Here, although the position in the depth direction of the lower end of the gate electrode 7 may be the same as the position in the depth direction of an upper end of the lower end of the second JFET region 8B, the position in the depth direction of the lower end of the gate electrode 7 is desirably deeper than the position in the depth direction of the upper end of the second JFET region 8B and is at a shallower position than the position in the depth direction of the lower end of the second JFET region 8B by taking manufacturing variations into consideration.

Furthermore, the width of the first JFET region 8A is desirably to 0.1 μm or more and the width of the second JFET region 8B is desirably 5 μm or less, yet these widths are not limited thereto.

An impurity concentration of the first JFET region 8A may be the same as or may be different from the impurity concentration of the second JFET region 8B.

Note that, as for the impurity concentration, in the present embodiment, for example, the first JFET region 8A and the second JFET region 8B are illustrated as n, the body regions 9 and the channel region 5 are illustrated as p, the drift region 10 is illustrated as n− of a low-concentration, the source region 3 and the drain region 11 are illustrated as n+ of a high concentration, and the contact region 4 is illustrated as p+ of a high concentration, yet are not limited thereto as long as an operation intended by the present embodiment can be implemented. For example, the first JFET region 8A and the second JFET region 8B may be n− of a low concentration.

The semiconductor device 1 according to the present embodiment can be formed using, for example, an n+ type Sic substrate, yet is not limited thereto, and the Si substrate or the like may be used. Furthermore, portions that are not especially described for a manufacturing method in this description can be formed by a general semiconductor device manufacturing method by, for example, forming the n+ type drain region 11 using the n+ type SiC substrate, and forming the n− type drift region 10 by epitaxial growth, and therefore detailed description will be omitted.

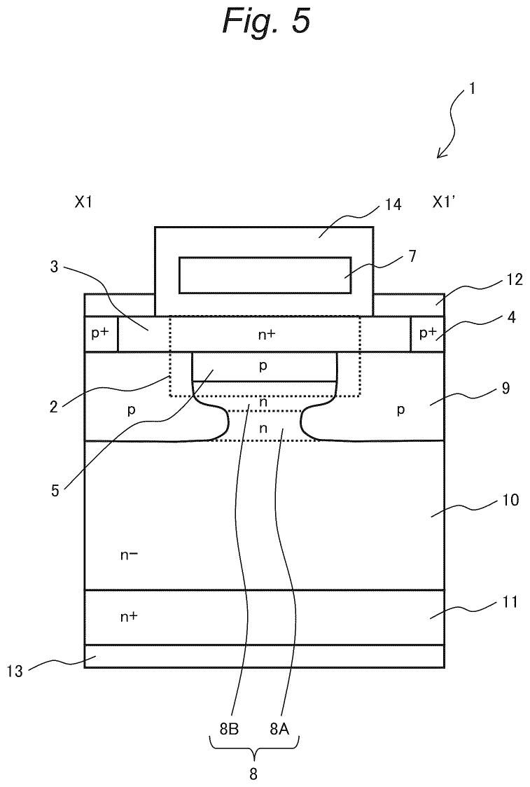

FIG. 5 is a cross-sectional view taken along line X1-X1′, corresponding to FIG. 2, and illustrating another example of the schematic configuration of the semiconductor device according to Embodiment 1.

Although FIG. 2 illustrates the shapes of the JFET region 8 and the body regions 9 as simple shapes such as rectangular shapes, the respective regions are actually made by ion implantation or epitaxial growth, and therefore the JFET region 8 and the body regions 9 may have such a shape that boundary portions smoothly connect to each other without corners as illustrated in FIG. 5, and may not have a definite boundary between the first JFET region 8A and the second JFET region 8B. This case is also the same as that in FIG. 2 in that the width of the second JFET region 8B is formed larger than the width of the first JFET region 8A.

The following embodiments will be described based on the shape illustrated in FIG. 5.

### Embodiment 2

Embodiment 2 is a variation of Embodiment 1, and is an embodiment where the impurity concentration of the first conductivity type of the second JFET region 8B is lower than the impurity concentration of the first conductivity type of the first JFET region 8A. Note that, desirably, the impurity concentration of the first conductivity type of the second JFET region 8B is 1×10¹⁵ cm−³ or more, and the impurity concentration of the first conductivity type of the first JFET region 8A is 1×10²⁰ cm⁻³ or less, yet are not limited thereto.

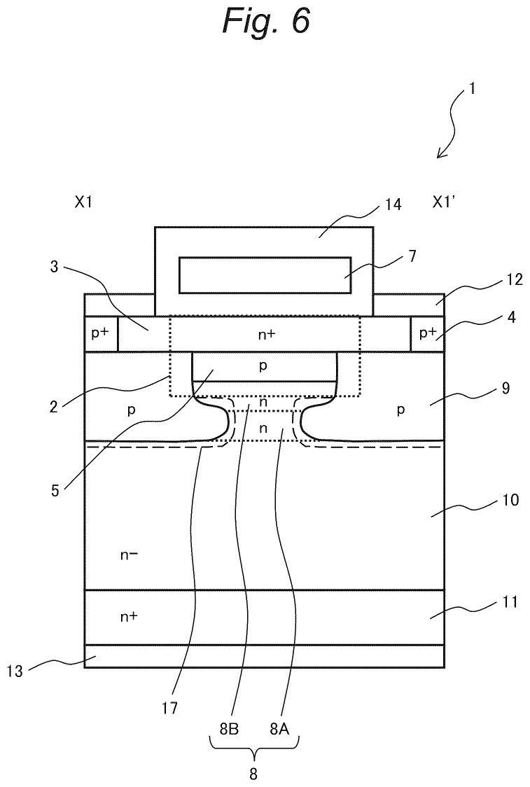

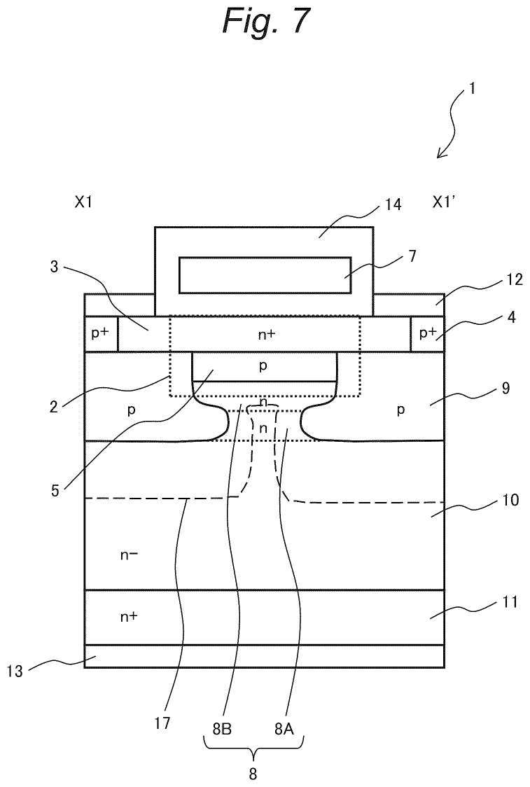

FIG. 6 is a cross-sectional view taken along line X1-X1′ and illustrating the schematic configuration of the semiconductor device according to Embodiment 2, and is a diagram schematically illustrating expansion of a depletion layer at a time of a normal operation. FIG. 7 is a cross-sectional view taken along line X1-X1′ and illustrating the schematic configuration of the semiconductor device according to Embodiment 2, and is a diagram schematically illustrating expansion of the depletion layer at a time of short-circuiting or at a time of blocking. As the impurity concentration becomes lower, the depletion layer 17 more readily expands. Note that, because expansion of the depletion layer 17 differs depending on a drain voltage value to be applied and an impurity concentration in each region, FIGS. 6 and 7 are merely examples.

As illustrated in FIG. 6, at the time of the normal operation, while the depletion layer 17 is likely to expand in the second JFET region 8B having the low concentration, the width of the second JFET region 8B is wide, and therefore the resistance in the second JFET region 8B is sufficiently low. Furthermore, while the first JFET region 8A has the narrow width, yet has a high concentration, and therefore the depletion layer 17 hardly extends from the body regions 9 and the resistance is sufficiently low, so that performance becomes high.

As illustrated in FIG. 7, because the second JFET region 8B has a low concentration at the time of short-circuiting or at the time of blocking, the depletion layer 17 is closed and pinches off in the second JFET region 8B to saturate a current. The depletion layer 17 pinches off in the second JFET region 8B, so that it is possible to reduce the electric field of the gate insulating film 6 on the bottom surfaces of the trenches 2.

Furthermore, the structure that the width of the second JFET region 8B is larger than the width of the first JFET region 8A and the impurity concentration of the first conductivity type of the second JFET region 8B is lower than the impurity concentration of the first conductivity type of the first JFET region 8A as in the present embodiment also has an advantage that electrical characteristics of the semiconductor device 1 are hardly affected by manufacturing variations in a wafer plane or between wafers. More specifically, the width of the second JFET region 8B is wide, so that, even when the width varies upon manufacturing, change in the resistance of the JFET region 8 becomes small. Furthermore, since the first JFET region 8A has a high concentration, the depletion layer 17 hardly extends, and, therefore even when the width varies upon manufacturing, the change in resistance of the JFET region 8 becomes little. Furthermore, although the first JFET region 8A needs such a width that the depletion layer 17 is not closed at the time of the normal operation, even when the width varies upon manufacturing, since the first JFET region 8A has a high concentration, the depletion layer 17 hardly extends, and therefore an influence due to variation of the width becomes little. As for the short circuit withstand time, the width of the second JFET region 8B to be pinched off at the time of short-circuiting is wider, so that the influence due to the variation of the width is little. Furthermore, it is possible to reduce necessity of precise exposure amount adjustment in a photo process at the time of manufacturing.

Next, characteristics of the semiconductor device 1 according to the present embodiment will be described.

The design window of the semiconductor device 1 according to the present embodiment can be made wider than that of the conventional technique.

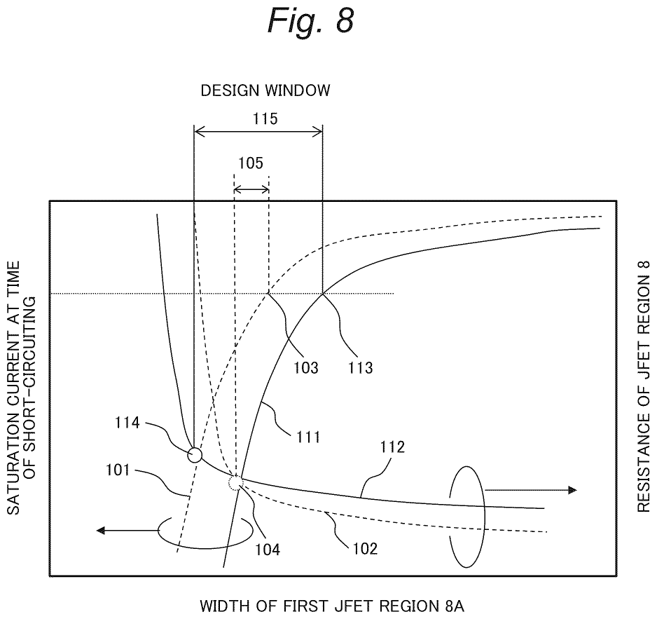

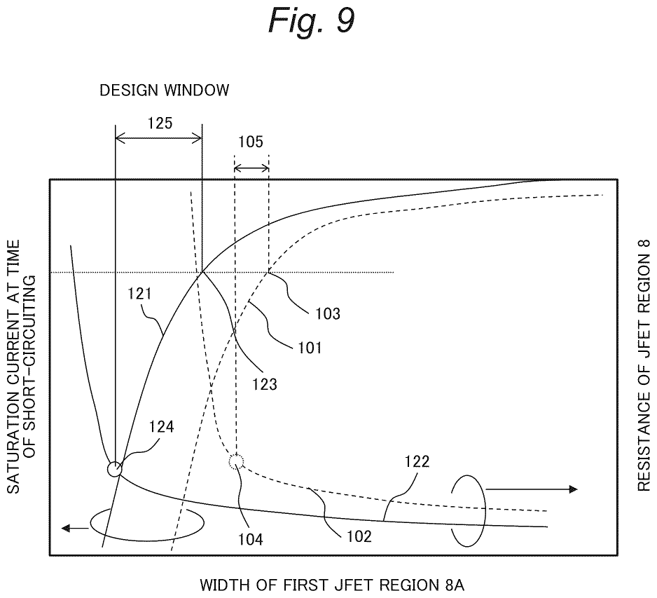

An example will be described with reference to FIGS. 8 and 9.

FIG. 8 is a diagram illustrating trade-off between performance and reliability in a case of a design focusing on reliability of the semiconductor device according to Embodiment 2. FIG. 9 is a diagram illustrating trade-off between performance and reliability in a case of a design focusing on performance of the semiconductor device according to Embodiment 2. In FIGS. 8 and 9, the horizontal axis indicates the width of the first JFET region 8A, the vertical axis on the left side indicates a saturation current at the time of short-circuiting as an example of the reliability, and the vertical axis on the right side indicates the resistance of the JFET region 8 as an example of the performance. Note that other indices may be used as indexes of the performance and the reliability.

In FIG. 8, 101 denotes characteristics of a saturation current at the time of short-circuiting in a conventional specification, and 102 denotes characteristics of a resistance of the JFET region 8 in the conventional specification. Here, the conventional specification is a specification in which there is not the second JFET region 8B and the entire JFET region 8 is constituted only by the first JFET region 8A. Note that the characteristics vary depending on the depth and the impurity concentration of the first JFET region 8A, and the characteristics illustrated in FIG. 8 are an example. Because the characteristics 101 of the saturation current at the time of short-circuiting in conventional specification increase as the width of the first JFET region 8A increases, a threshold point 103 that is equal to a threshold of the saturation current at the time of short-circuiting to be allowed becomes an upper limit of the design of the width of the first JFET region 8A. The characteristics 102 of the resistance of the JFET region 8 in the conventional specification increase as the width of the first JFET region 8A becomes smaller, and rapidly increases when the width of the first JFET region 8A becomes smaller than a threshold point 104 at which the depletion layer 17 pinches off in the JFET region 8 at the time of the normal operation. Accordingly, the threshold point 104 is the lower limit of the design of the width of the first JFET region 8A. A region between the upper limit and a lower limit of the design is the design window. A design window 105 of the width of the first JFET region 8A in the conventional specification has a size illustrated in FIG. 8.

By contrast with this, 111 denotes characteristics of a saturation current at the time of short-circuiting in the specification focusing on reliability in the present embodiment, and 112 denotes characteristics of a resistance of the JFET region 8 in the specification focusing on reliability in the present embodiment.

In the specification focusing on reliability and the specification focusing on performance according to the present embodiment, the second JFET region 8B having a wider width than that of the first JFET region 8A and having a lower impurity concentration of the first conductivity type is added. An example will be used and described where the impurity concentration of the second JFET region 8B is set to a lower concentration than that of the JFET region 8 in the conventional specification, and the impurity concentration of the first JFET region 8A is set to a higher concentration than that of the JFET region 8 in the conventional specification, yet the impurity concentrations are not limited thereto.

The specification focusing on reliability in the present embodiment is implemented in, for example, a case where the impurity concentration of the second JFET region 8B is a relatively low concentration, a case where the width of the second JFET region 8B is relatively narrow, or a case where the impurity concentration of the first JFET region 8A takes a value close to that of the impurity concentration of the second JFET region 8B, yet is not limited thereto. Note that the characteristics change depending on the depth and the impurity concentration of the first JFET region 8A and the width, the depth, and the impurity concentration of the second JFET region 8B, and therefore the characteristics illustrated in FIG. 8 are an example.

As for the index of reliability, according to characteristics 111 of a saturation current at the time of short-circuiting in the specification focusing on reliability, the depletion layer 17 is closed and pinches off in the second JFET region 8B earlier than the first JFET region 8A at a time of a high voltage to prevent a large current (short-circuit current) from flowing, so that, even if the width of the first JFET region 8A is the same, a saturation current at the time of short-circuiting can be reduced compared to the characteristics 101 of the saturation current at the time of short-circuiting in the conventional specification. Accordingly, a threshold point 113 corresponding to the threshold point 103 moves rightward more than the threshold point 103, and the upper limit of the design of the width of the first JFET region 8A expands.

As for the index of performance, according to the characteristics 112 of the resistance of the JFET region 8 in the specification focusing on reliability, although there is also a region in which the resistance is more or less higher than that of the characteristics 102 of the resistance of the JFET region 8 in the conventional specification, the second JFET region 8B has the wider width than that of the first JFET region 8A and the first JFET region 8A has a higher concentration than that in the conventional specification, the threshold point 114 (pinch-off point) at which the depletion layer 17 pinches off in the first JFET region 8A at the time of the normal operation can be set closer to the left side than the threshold point 104 in the conventional specification. As described above, the threshold point 114 moves leftward more than the threshold point 104, so that the lower limit of the design of the width of the first JFET region 8A expands.

Accordingly, a design window 115 of the width of the first JFET region 8A in the specification focusing on the reliability according to the present embodiment can be made wider than the design window 105 of the width of the first JFET region 8A in the conventional specification.

Note that, although FIG. 8 illustrates an example where the impurity concentration of the first JFET region 8A in the specification focusing on the reliability is made higher than the impurity concentration of the first JFET region 8A in the conventional specification, the impurity concentration of the first JFET region 8A may be made the same as the impurity concentration of the first JFET region 8A in the conventional specification. In this case, the threshold point 114 is close to the threshold point 104, and therefore although the lower limit of the design of the width of the first JFET region 8A does not change much, the saturation current at the time of short-circuiting further lowers compared to FIG. 8, so that the upper limit of the design is expanded. Accordingly, it is also possible to make the design window 115 wider than the design window 105 in this case.

The design focusing on the performance in FIG. 9 is such a specification that the resistance of the JFET region 8 is lowered and the current at the time of the normal operation is increased compared to the design focusing on the reliability in FIG. 8.

In FIG. 9, the characteristics 101 of the saturation current at the time of short-circuiting in the conventional specification and the characteristics 102 of the resistance of the JFET region 8 in the conventional specification are the same as those in FIG. 8.

By contrast with this, 121 denotes characteristics of a saturation current at the time of short-circuiting in the specification focusing on performance according to the present embodiment, and 122 denotes characteristics of a resistance of the JFET region 8 in the specification focusing on performance according to the present embodiment.

The specification focusing on the performance according to the present embodiment can be implemented by, for example, making the impurity concentration of the second JFET region 8B much higher than the impurity concentration of the second JFET region 8B in the specification focusing on the reliability while satisfying a condition that the second JFET region 8B has a lower concentration than that of the first JFET region 8A. Note that, the present invention is not limited thereto, and it is possible to make at least one of the impurity concentration of the first JFET region 8A and the impurity concentration of the second JFET region 8B higher than that in the specification focusing on reliability while satisfying the condition that the second JFET region 8B has a lower concentration than that of the first JFET region 8A. Note that the characteristics change depending on the depth and the impurity concentration of the first JFET region 8A and the width, the depth, and the impurity concentration of the second JFET region 8B, and therefore the characteristics illustrated in FIG. 9 are an example.

As for the index of the performance, the resistance is made lower in characteristics 122 of the resistance of the JFET region 8 in the specification focusing on the performance than that in the characteristics 102 of the resistance of the JFET region 8 in the conventional specification. Consequently, it is possible to increase the current at the time of the normal operation, and improve the performance. The first JFET region 8A has a high concentration, and therefore does not pinch off even if the width of the first JFET region 8A is reduced to a narrower width than that in the conventional specification. Accordingly, a threshold point 124 at which the depletion layer 17 pinches off in the first JFET region 8A at the time of the normal operation moves leftward more than the threshold point 104. Note that the second JFET region 8B has a wide width and does not pinch off at the time of the normal operation.

As for the index of the reliability, the saturation current at the time of short-circuiting is larger in the characteristics 121 of the saturation current at the time of short-circuiting in the specification focusing on the performance than the characteristics 101 of the saturation current at the time of short-circuiting in the conventional specification, and, while a threshold point 123 corresponding to the threshold point 103 moves leftward more than the threshold point 103, a threshold point 124 corresponding to the threshold point 104 also moves leftward, a design window 125 of the width of the first JFET region 8A in the specification focusing on the performance is wider than the design window 105 of the width of the first JFET region 8A in the conventional specification. Furthermore, at the time of the high voltage, the depletion layer 17 is closed and pinches off in the second JFET region 8B, so that it is possible to prevent a large current (short-circuit current) from flowing, and consequently it is also possible to secure reliability while improving the performance.

### Embodiment 3

Embodiment 3 is a variation of Embodiment 1, and is an embodiment where the impurity concentration of the first conductivity type of the second JFET region 8B is higher than the impurity concentration of the first conductivity type of the first JFET region 8A. Note that, desirably, the impurity concentration of the first conductivity type of the first JFET region 8A is 1×10¹⁵ cm⁻³ or more, and the impurity concentration of the first conductivity type of the second JFET region 8B is 1×10²⁰ cm⁻³ or less, yet the impurity concentrations are not limited thereto.

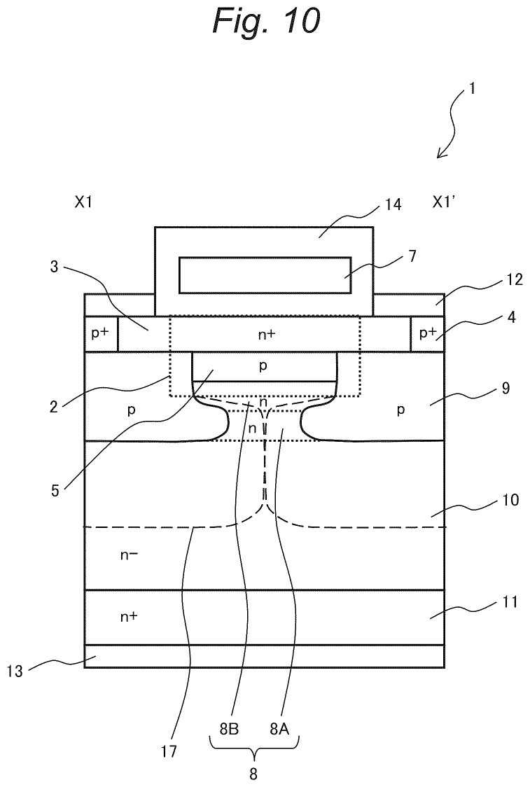

FIG. 10 is a cross-sectional view taken along line X1-X1′ and illustrating the schematic configuration of the semiconductor device according to Embodiment 3, and is a diagram schematically illustrating expansion of the depletion layer at the time of short-circuiting or at the time of blocking.

Embodiment 3 differs from Embodiment 2 in that the depletion layer 17 is closed and pinches off in the first JFET region 8A and part of the drift region 10. A location at which the depletion layer 17 is closed and pinches off is different from that in Embodiment 2, yet the width of the channel region 5 and the width of the first JFET region 8A can be also designed independently in the present embodiment. Furthermore, compared to Embodiment 2, it is possible to increase a route in which the depletion layer 17 pinches off, so that the resistance in the route through which the saturation current flows becomes high, and it is possible to suppress the saturation current.

Furthermore, although not illustrated, the second JFET region 8B also has a high impurity concentration at the time of the normal operation, so that the resistance becomes low.

### Embodiment 4

Embodiment 4 is a variation of Embodiment 1, and is an embodiment where part of the second JFET region 8B includes a channel punch-back region 15 having a higher impurity concentration of the first conductivity type than that of the other part of the second JFET region 8B.

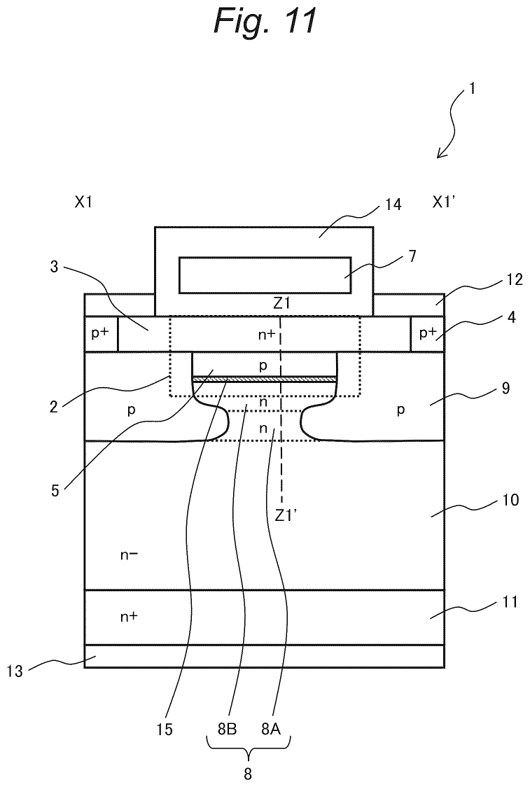

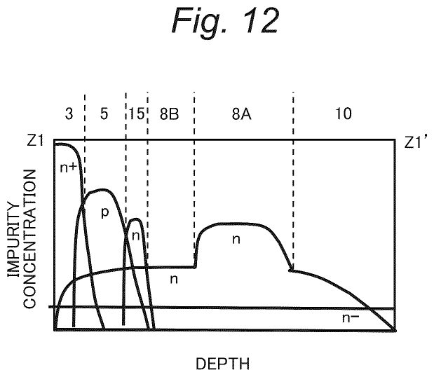

FIG. 11 is a cross-sectional view taken along line X1-X1′ and illustrating the schematic configuration of the semiconductor device according to Embodiment 4. FIG. 12 is a diagram illustrating an impurity concentration profile in the depth direction along line Z1-Z1′ in FIG. 11. In FIG. 12, the horizontal axis indicates a depth, and the vertical axis indicates an impurity concentration. Note that FIG. 12 illustrates an example where the channel punch-back region 15 is provided compared to Embodiment 2, the channel punch-back region 15 is not limited thereto and may be applied to Embodiment 1 or Embodiment 3.

According to the present embodiment, in addition to the effects according to Embodiment 1 and Embodiment 3, it is possible to prevent expansion of a range of the impurity concentration of the second conductivity type of the channel region 5 by the channel punch-back region 15 as illustrated in FIG. 12.

### Embodiment 5

Embodiment 5 is a variation of Embodiment 1, and is an embodiment where the impurity concentration of the first conductivity type of the first JFET region 8A and the impurity concentration of the first conductivity type of the second JFET region 8B are different, and a JFET region having a higher impurity concentration of the first conductivity type among the first JFET region 8A and the second JFET region 8B includes between this JFET region and the body regions 9, a low concentration region in which the impurity concentration of the first conductivity type is lower than that of the other part or an intrinsic region 16 that is not doped with an impurity of the first conductivity type.

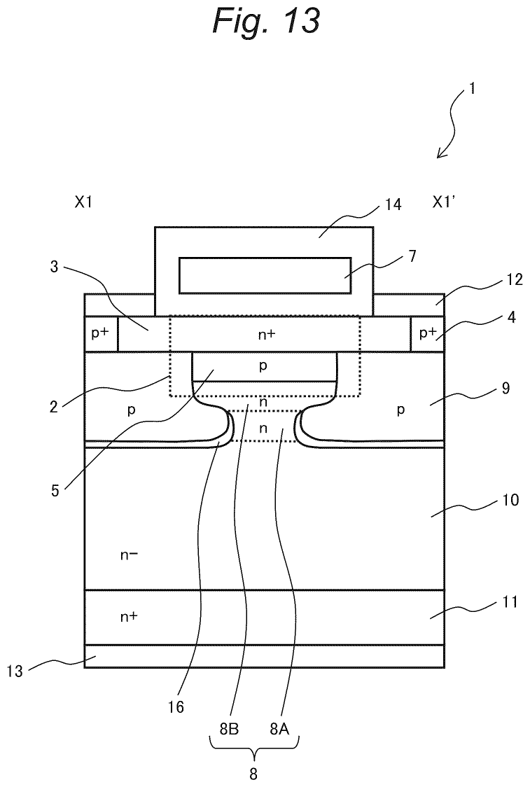

FIG. 13 is a cross-sectional view taken along line X1-X1′ and illustrating the schematic configuration of the semiconductor device according to Embodiment 5.

FIG. 13 illustrates an example where, when the first JFET region 8A has a higher concentration than that of the second JFET region 8B as in Embodiment 2, the intrinsic region 16 is provided to the first JFET region 8A having the high concentration. Note that the present invention is not limited thereto, and a low concentration region having an impurity concentration of the first conductivity type lower than that of the other part may be provided instead of the intrinsic region 16. The low concentration region desirably has a sufficiently low concentration.

In a case where, for example, the second JFET region 8B has a very low concentration, the first JFET region 8A needs to have a certain level of a high concentration to lower the resistance of the JFET region 8. However, in this case, a junction electric field at a boundary between the first JFET region 8A and the body region 9 becomes high, and an undesirable operation such as avalanche multiplication and a hot carrier effect may be performed. Hence, by providing the intrinsic region 16 (i layer) as illustrated in FIG. 13, it is possible to reduce a maximum electric field by the following equation.

Emax (with the i layer)/Emax (without the i layer)=(1+d²/Wd²)^{0.5}−d/Wd holds, and, here, Wd represents the width of a depletion layer at a pn junction and d represents the width of the i layer.

Note that, in a case where the second JFET region 8B has a higher concentration than that of the first JFET region 8A as in Embodiment 3, the low impurity concentration region or the intrinsic region 16 may be provided to the second JFET region 8B having the high concentration.

### Embodiment 6

Embodiment 6 is a variation of Embodiment 1.

In the semiconductor device 1 according to the present embodiment, at least part of parameters of the width, the depth, and the impurity concentration of the first conductivity type of the first JFET region 8A, and the width, the depth, and the impurity concentration of the first conductivity type of the second JFET region 8B are set such that (1) the integration value of the dose amount of the JFET region 8 becomes minimum, (2) the maximum value of the quasi Fermi level of the JFET region 8 becomes minimum at the time of application of a voltage at the time of the normal operation, and (3) the depth of the depletion layer 17 that expands to the drift region 10 at the time of short-circuiting becomes maximum.

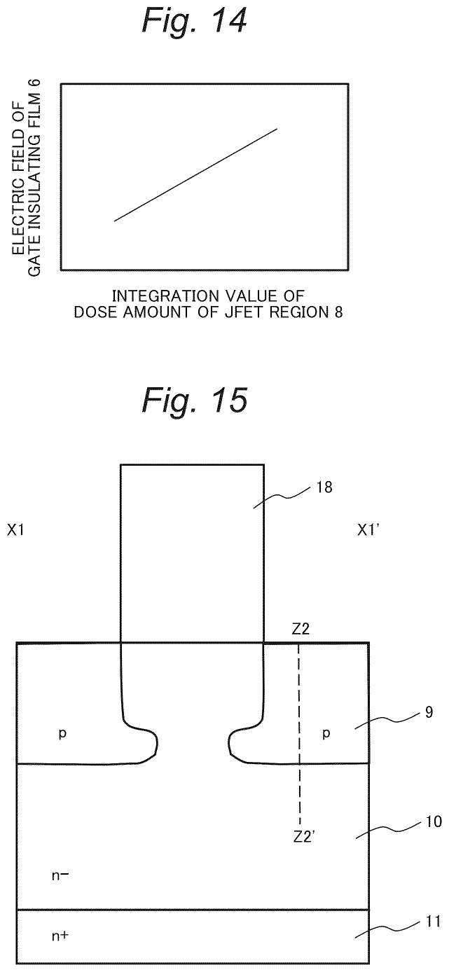

FIG. 14 is a diagram describing a relationship between an integration value of a dose amount of a JFET region and the electric field of a gate insulating film in the semiconductor device according to Embodiment 6. In FIG. 14, the horizontal axis indicates an integration value of the dose amount of the JFET region 8, and the vertical axis indicates the electric field of the gate insulating film 6 at the time of blocking. Note that the integration value of the dose amount of the JFET region 8 on the horizontal axis is an integration value of the dose amount of the entire JFET region 8 that is a combination of the first JFET region 8A and the second JFET region 8B.

According to the condition (1), the electric field of the gate insulating film 6 at the time of blocking can be reduced. Note that, although an example where the relationship between both is substantially linear in the range of the design according to the present embodiment as illustrated in FIG. 14 has been described, the present invention is not limited thereto.

According to the condition (2), it is possible to reduce the on-resistance of the entire JFET region 8 at the time of the normal operation.

According to the condition (3), it is possible to minimize the current flowing in the JFET region 8 at the time of short-circuiting, and reduce the saturation current.

Furthermore, (4) the design windows 115 and 125 (see FIGS. 8 and 9) of the width of the first JFET region 8A may be set such that the design windows 115 and 125 are a predetermined width or more, or may be maximum in combination with Embodiment 2.

An example of a design method may include, for example, using at least part of parameters of the width, the depth, and the impurity concentration of the first conductivity type of the first JFET region 8A, and the width, the depth, and the impurity concentration of the first conductivity type of the second JFET region 8B as variables, fixing the rest of parameters, and finding a numerical value satisfying requirement of the conditions (1) to (3) or the conditions (1) to (4). Note that this design may be conceived by people, or may be made using an optimization system of Artificial Intelligence (AI).

According to the present embodiment, it is possible to implement the semiconductor device that can achieve both of the performance and the reliability.

### Embodiment 7

Embodiment 7 is a variation of Embodiment 1.

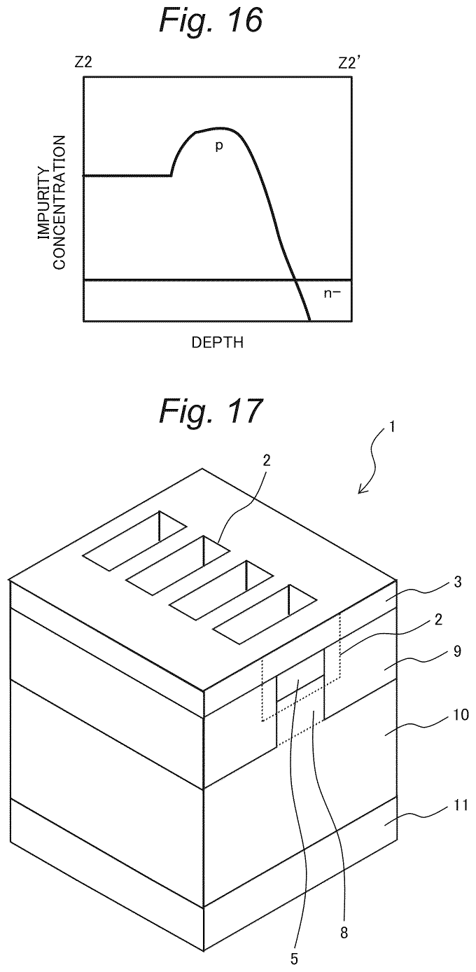

FIG. 15 is a cross-sectional view taken along X1-X1′ and describing a manufacturing method of the semiconductor device according to Embodiment 7. FIG. 16 is a diagram describing the manufacturing method of the semiconductor device according to Embodiment 7, and is a diagram illustrating an impurity concentration profile in the depth direction along line Z2-Z2′ in FIG. 15. In FIG. 16, the horizontal axis indicates a depth, and the vertical axis indicates an impurity concentration.

In the present embodiment, when the body regions 9 are formed by using a resist 18 as a mask, ions are implanted such that a peak position in the depth direction of the impurity concentration of the second conductivity type comes at a position in the depth direction of the first JFET region 8A to form such a shape that part of the body regions 9 protrudes, so that it is possible to form the body regions 9 having such a shape that the width of the second JFET region 8B is larger than the width of the first JFET region 8A by implanting ions once.

Consequently, the semiconductor device 1 according to the present embodiment has a structure that the peak position in the depth direction of the impurity concentration of the second conductivity type of the body regions 9 overlaps the position in the depth direction of the first JFET region 8A.

Note that the present invention is not limited to such a manufacturing method and structure, and the body region 9 having such a shape that the width of the second JFET region 8B is larger than the width of the first JFET region 8A can be formed in two steps. In this case, the impurity concentration of the second conductivity type of the body region 9 may not have a peak in the depth direction.

While the embodiments of the present invention have been described above, the present invention is not limited to the configurations described in the embodiments, and various variations can be made within the scope of the technical concepts of the present invention. Furthermore, some or all of the configurations described in the embodiments may be applied in combination.

### REFERENCE SIGNS LIST

1 Semiconductor device
2 Trench
3 Source region
4 Contact region
5 Channel region
6 Gate insulating film
7 Gate electrode
8 JFET region
8A First JFET region
8B Second JFET region
10 Drift region
11 Drain region
12 Source electrode
13 Drain electrode
14 Interlayer insulating film
15 Channel punch-back region
16 Intrinsic region
17 Depletion layer
18 Resist

1. A semiconductor device comprising:
a plurality of trenches that have a longitudinal direction in a first direction and have a lateral direction in a second direction in plan view, and are aligned in the second direction;
a source region of a first conductivity type that includes a region having a fin structure at least partially partitioned by the plurality of trenches;
a channel region of a second conductivity type that is in contact with a lower surface of the source region and has a fin structure partitioned by the plurality of trenches;
a gate insulating film that is disposed inside the trenches;
a gate electrode that includes a region at least partially disposed inside the trenches;
a JFET region of the first conductivity type that is disposed below the channel region; and
a body region of the second conductivity type that is disposed on a lateral side of the JFET region, wherein
end parts in the first direction of bottom surfaces of the plurality of trenches are disposed in the body region,
the channel region is connected to the body region, and a channel current flows in the channel region in a vertical direction,
the JFET region includes a first JFET region and a second JFET region disposed closer to a side of the channel region than the first JFET region, and
a length in the first direction of the second JFET region is longer than a length in the first direction of the first JFET region.

2. The semiconductor device according to claim 1, wherein
an impurity concentration of the first conductivity type of the second JFET region is lower than an impurity concentration of the first conductivity type of the first JFET region.

3. The semiconductor device according to claim 2, wherein
the impurity concentration of the first conductivity type of the second JFET region is 1×10¹⁵ cm⁻³ or more, and
the impurity concentration of the first conductivity type of the first JFET region is 1×10²⁰ cm⁻³ or less.

4. The semiconductor device according to claim 1, wherein
an impurity concentration of the first conductivity type of the second JFET region is higher than an impurity concentration of the first conductivity type of the first JFET region.

5. The semiconductor device according to claim 4, wherein
the impurity concentration of the first conductivity type of the first JFET region is 1×10¹⁵ cm⁻³ or more, and
the impurity concentration of the first conductivity type of the second JFET region is 1×10²⁰ cm⁻³ or less.

6. The semiconductor device according to claim 1, wherein
a peak position in a depth direction of an impurity concentration of the second conductivity type of the body region overlaps a position in the depth direction of the first JFET region.

7. The semiconductor device according to claim 1, wherein
a position in a depth direction of a lower end of the gate electrode disposed inside the trenches overlaps a position in the depth direction of the second JFET region.

8. The semiconductor device according to claim 1, wherein
part of the second JFET region includes a channel punch-back region having a higher impurity concentration of the first conductivity type than that of an other portion of the second JFET region.

9. The semiconductor device according to claim 1, further comprising:
a contact region that is provided on a front surface side of the body region and has a higher impurity concentration of the second conductivity type than that of the body region; and
a source electrode that is connected to the contact region and the source region.

10. The semiconductor device according to claim 1, wherein
a length in the first direction of the first JFET region is 0.1 μm or more, and
a length in the first direction of the second JFET region is 5 μm or less.

11. The semiconductor device according to claim 1, wherein
an impurity concentration of the first conductivity type of the first JFET region and an impurity concentration of the first conductivity type of the second JFET region are different, and
a JFET region having a higher impurity concentration of the first conductivity type among the first JFET region and the second JFET region includes a low concentration region or an intrinsic region between the JFET region and the body region, the low concentration region having a lower impurity concentration of the first conductivity type than that of an other region, or the intrinsic region not being doped with an impurity of the first conductivity type.

12. The semiconductor device according to claim 1, further comprising:
a drift region of the first conductivity type that is disposed below the JFET region; and
a drain region of the first conductivity type that is disposed

13. The semiconductor device according to claim 12, wherein
at least part of parameters of a length in the first direction, a depth, and an impurity concentration of the first conductivity type of the first JFET region, and a length in the first direction, a depth, and the impurity concentration of the first conductivity type of the second JFET region are set such that an integration value of a dose amount of the JFET region becomes minimum, a maximum value of a quasi Fermi level of the JFET region at a time of application of a voltage at a time of a normal operation becomes minimum, and a depth of a depletion layer expanding to the drift region at a time of short-circuiting becomes maximum.

14. The semiconductor device according to claim 1, wherein
a length in the first direction of the trenches is longer than the length in the first direction of the second JFET region.
